(19) United States
(12) Patent Application Publication
(10) Pub. No.: US 2026/0088086 A1
(43) Pub. Date: Mar. 26, 2026

(54) Programming of the High Resistive State of a Resistive Memory Element

(71) Applicant: WEEBIT NANO LTD, Hod Hasharon (IL)

(72) Inventors: Gabriel Molas, Fontanil Cornillon (FR); Ishai Naveh, Clearwater, FL (US); Giuseppe Piccolboni, Grenoble (FR)

(73) Assignee: WEEBIT NANO LTD, Hod Hasharon (IL)

(21) Appl. No.: 19/325,941

(22) Filed: Sep. 11, 2025

(30) Foreign Application Priority Data
Sep. 23, 2024 (FR) FR2410111

(51) Int. Cl. G11C 13/00; G11C 29/50

(52) U.S. Cl. CPC G11C 13/0069; G11C 13/0028; G11C 13/004; G11C 29/50004; G11C 2013/0078; G11C 2213/34; G11C 2213/79

(57) ABSTRACT

A method (100) of programming a high resistive state of a memory element (Stck) part of a resistive random access memory (MEM), the method (100) comprising: an initial step (S110) of writing the high resistive state of the memory element (Stck); and a reconditioning step (S140) following the initial step (S110) of writing the high resistive state (HRS), the reconditioning step (S140) comprising at least one cycle of operations comprising, in this order: a reconditioning set operation (SET_{rec}) that consists in running a reconditioning set current (I_{rec.set}) through the memory element (Stck), the reconditioning set current (I_{rec.set}) having an absolute value lower than the nominal programming current (I_{p.set}); and a reconditioning reset operation (RESET) that consists in running a reconditioning reset current (Iᵣₑₛₑₜ) through the memory element (Stck).

### CROSS-REFERENCE TO RELATED APPLICATION

The present application claims priority to French Patent Application No. FR2410111 filed on September 23, 2024, the contents of which are hereby incorporated by reference in their entirety.

### FIELD OF THE INVENTION

The technical domain of the invention is that of Resistive Random Access Memory (ReRAM) or Resistive RAM, that each comprise a memory element whose resistive state defines a bit of information. More specifically, the invention concerns a programming method of the ReRAM.

### BACKGROUND OF THE INVENTION

Non-volatile memory (NVM) is a kind of computer memory able to retain information even when its power source is turned off. Examples of non-volatile memories include read-only memories (ROM), erasable ROM (EPROM), flash memories, ferroelectric random-access memories (FRAM), magnetoresistive random access memories (MRAM), phase-change memories (PCM) and resistive random access memories (ReRAM).

The latter type of memories, the ReRAM, is typically formed by an array of stacks Stck of a layer Diel made of a dielectric solid-state material and two electrodes El1 and El2 between which the layer Diel is interposed, as illustrated by FIG. 1. Such a structure constitutes a memory bit element, or memory element, and works typically by changing the electrical resistance of the layer Diel by forming and dissolving a conductive filament in the otherwise non-conductive dielectric layer. The dielectric layer may be formed from, for example, a chalcogenide, a perovskite or an oxide of a transition metal such as hafnium oxide (HfOx).

A memory is formed by an array of such memory bit elements each forming the core of one bit cell. The present description will take ax example a ReRAM employing oxides of transition metals to form the dielectric solid-state material, i.e. an OxRAM.

At the end of its manufacturing process, a ReRAM device typically undergoes an initialization stage designed to activate each of its individual memory cells. This stage can be part of the manufacturing flow or is performed just after and is generally performed only once, before the device is used to store data through set or reset operations. The purpose of the initialization stage is to provide better control over the electrical characteristics of the memory cells and to improve device yield by enhancing the stability of key functional parameters such as current and resistance values. This process is sometimes carried out using a so-called FORM algorithm. One may refer to US 2021/110870 A1 and US 2015/0287919 A1. Once initialization is complete, the memory device is ready for normal operation and data storage. Information can then be written by applying set and reset operations, which define the resistance states — and therefore the bit values — of the memory elements, as described below. As illustrated by FIG. 1, during a set operation SET, application of a given voltage between the two electrodes generates a set electrical current I_{p.set} along with an associated electrical field in a first direction d1, from the electrode El2 to the electrode El1. This current can lead to the formation of an electrically conductive filament Fil in the otherwise electrically insulating layer Diel, due to the formation and diffusion of pairs of oxygen ions Oxy and oxygen vacancies V_{Oxy} in the volume of the dielectric layer Diel. The bit element is then put in a low resistance state or LRS. The higher the set current, the larger the filament and the lower the resistance of the bit element.

Conversely, during a reset operation RESET, an opposite voltage is applied to generate a reset electrical current I_{p.res} running between the two electrodes El1 and El2 in a second direction d2, opposite to the first direction. The reset current can dissolve the electrically conductive filament Fil created during the set operation Set, thus forming a dissolved filament DisFil and increasing the electrical resistance of the bit element. The bit element is then put in a high resistance state or HRS.

Each of the LRS and HRS states can be associated to a bit value of a digital memory. During a read operation, a read current is run between the two electrodes to evaluate the resistive state of the bit element, and thus the associated bit value. The absolute value of the read current is lower than both the set current and the read current so as to not modify the state of the dielectric layer.

The formation process of the filament and its final configuration, which determines the resistance of the memory element in the LRS are stochastic in nature. As a consequence, the characteristics of the bit cells spread over ranges. In this context, FIG. 2 illustrates the resistances of a collection of bit cells of a same array.

FIGS. 2(A)and (B) illustrates the probability Pr for each of the bit cells of an array to take a given resistance value R(Ω), in an ideal case and in a more realistic case, respectively. In the ideal case, only two values are possible: a unique first value for the resistance of the Low Resistance State LRS and a second unique value for the resistance of the High Resistance State HRS.

In the ideal model, only these two states are accessible to the bit cells, and each one has a unique, well defined, resistance value. However, in practice, the resistance values spread over ranges that can each be described as a probability density having the shape of a peak centered on a given value (R_{0_LRS} and R_{0_HRS} for the two states LRS and HRS, respectively) and presenting a standard deviation σ (similar repartitions for LRS and HRS in this example, for the sake of keeping the explanation simple), as illustrated by FIG. 2(B).

As illustrated by FIG. 2(B), two states LRS and HRS can in fact be close to one another. The distributions of these two states can even overlap. This can lead to a confusion between an LRS state and an HRS state and errors during the read operation of data stored in a ReRAM.

Depending on the absolute value I_{prog} of the programming current defining the set current and the reset current, resistance values of the HRS and the LRS vary.

As illustrated by FIG. 3, for a given memory element, a set operation with a first programming current I_{Prog}1 will lead to a first filament Fil1 of a given width, and thus to a LRS of a first resistive value R1_{LRS}. With the same programming current I_{Prog}1, a reset operation RESET will dissolve the filament to some extent, and thus to a HRS of a first given resistive value R1_{HRS}. These results are illustrated on the left-hand side of FIG. 3.

The right-hand side of FIG. 3 illustrates the results of the same set and reset operations as the left-hand side, except that a stronger programming current IProg2 is used. The filament Fil2 formed by the set operation is thicker that the filament Fil1 and harder to dissolver by the reset operation RESET, which leads to a LRS of a second resistive value R2_{LRS} lower than the first resistive value R1_{LRS}, and to a HRS of a second resistive value R2_{HRS} lower that first resistive value R1_{HRS}.

Thus, programming LRS of a memory element with a stronger set current can help forming a thicker filament Fil. An advantage of this method is that it can help forming LRS with lower resistance values. However, thicker filaments are harder to dissolve, which leads to relatively low resistance value for the HRS, which goes against the overall objective of increasing the margin in resistance between LRS and HRS. Further, the HRS retention capacity of the memory degrades as thicker filaments more easily reform themselves over time.

We see that there is a need of improving the writing method employed in OxRAM, and more generally speaking in ReRAMs.

### OBJECT OF THE INVENTION

In the context described above, the inventors propose a programming method of a ReRAM memory element that allows setting a high resistance value for the HRS while maintaining a low resistive value for the LRS, and thus that improves the resistance margin between LRS and HRS.

### SUMMARY OF THE INVENTION

To this effect, a first aspect of the invention relates to a method of programming a high resistive state of a memory element part of a resistive random access memory, the random access memory being configured to program a low resistive state of the memory element by running a nominal programming current in a first direction through the memory element, the method comprising: an initial step of writing the high resistive state of the memory element, consisting in running a reset current through the memory element in a second direction, opposite to the first direction; and a reconditioning step following the initial step of writing the high resistive state, the reconditioning step comprising at least one cycle of operations comprising, in this order: a reconditioning set operation that consists in running a reconditioning set current in the first direction through the memory element, the reconditioning set current having an absolute value lower than the nominal programming current; and a reconditioning reset operation that consists in running a reconditioning reset current in the second direction through the memory element, wherein the reconditioning step increases the resistive value of the memory element obtained by the initial step of writing the high resistive state.

By the application of a reconditioning operation, that includes at least one set operation followed by one reset operation, the set operation employing a programming current lower that the nominal current used in normal writing operation of a LRS, the programming method according to the invention allows reaching a resistive value for the HRS that is higher than would be achievable through conventional HRS writing methods.

Advantageously, the resistance margin between the LRS and the HRS is widened, which facilitates the reading operation and generally improve the reliability of a ReRAM employing this programming method.

According to further non limitative features of the first aspect of the invention, either taken alone or in any technically feasible combination:

the method can further comprise: a first read operation measuring a resistive value of the resistive element after the initial step of performing the reset operation ; and a test step in which the measured resistive value is compared to a threshold value, wherein the reconditioning step is performed when the measured resistive value is lower than the threshold value;

the method can further comprise: a second read operation measuring a reconditioned resistive value of the resistive element after the reconditioning step has been performed; and a second test step in which the measured reconditioned resistive value is compared to the threshold value, wherein the reconditioning step is performed again when the measured reconditioned resistive value is lower than the threshold value;

the reconditioning step can comprise exactly one occurrence of the cycle of operations;

the reconditioning step can comprise more than one occurrence of the cycle of operations;

the reconditioning step can comprise more than one and less than 20 occurrences of the cycle of operations;

the nominal programming current can have an absolute value comprised between 175 µA and 225 µA, and the reconditioning set current can have an absolute value comprised between 75 µA and 125 µA;

the initial step of writing the high resistive state of the memory element can dissolve an electrically conductive filament formed in the memory element; the reconditioning set operation can reform the dissolved filament; and the reconditioning reset operation can dissolve the reformed filament;

the method can be performed during a normal operation of the resistive random access memory (MEM), and not during a manufacturing stage and/or initialization of the resistive random access memory (MEM).

A second aspect of the invention relates to a ReRAM memory device comprising an array of bit cells controlled by a column multiplexer circuit and a row driver circuit configured to write a high resistive state of a memory element of the bit cell according to the method of the first aspect of the invention. The ReRAM can be an OxRAM.

A third aspect of the invention relates to an embedded system comprising a microprocessor and the memory device according to the second aspect of the invention arranged to be in communication with the microprocessor.

### BRIEF DESCRIPTION OF DRAWINGS

Many other features and advantages of the present invention will become apparent from reading the following detailed description, when considered in conjunction with the accompanying drawings, in which:

FIG. 1 illustrates the principle of operation of a ReRAM;

FIG. 2 illustrates the repartition of the resistivities of bit cells of a resistive memory;

FIG. 3 illustrates the influence of the programming current intensity on the resistive values of LRS and HRS of a memory element;

FIG. 4 illustrates effects of the method according to the invention;

FIG. 5 is a diagram of a HRS writing method;

FIG. 6 represents currents applied to a memory element according to the method of FIG. 5;

FIG. 7 illustrates phenomenologically the working of the method of FIG. 5 and FIG. 6;

FIG. 8 shows graphs explaining the functioning of the method of FIG. 5;

FIG. 9 is a graph justifying specific values for the current intensity used in the method of FIG. 5;

FIG. 10 illustrates a ReRAM memory incorporating the memory element illustrated by FIG. 4; and

FIG. 11 illustrates an embedded systems incorporating the memory illustrated by FIG. 10.

### DETAILED DESCRIPTION OF A GENERIC EMBODIMENT OF THE INVENTION

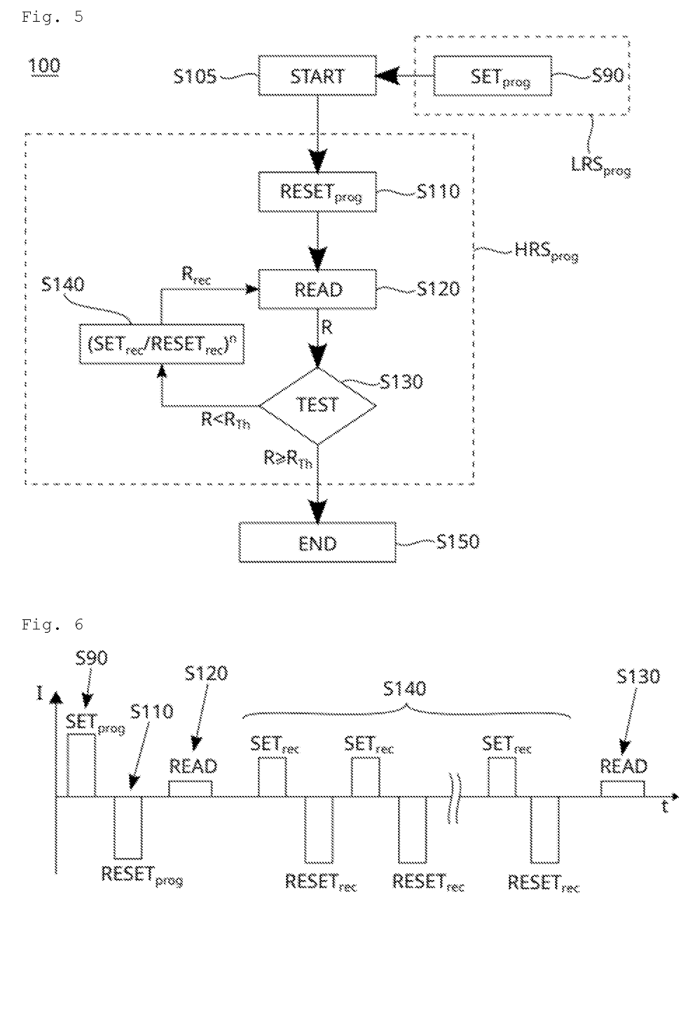

A generic embodiment of the invention will be described hereunder, with the help of FIGS. 4 to 11.

FIG. 4 represents cumulative probabilities Cum.Pr for memory elements of a ReRAM to present a given resistance R, expressed in ohm, for their respective low resistive state LRS and high resistance state HRS.

At (A), FIG. 4 represents a situation in which there is an overlap indicated as Over between the resistances of the low resistive state LRS and the conventional high resistive state HRS_{Conv} obtained with conventional writing methods. This overlap is a source of difficulties to use the ReRAM.

At (B), FIG. 4 represents the objective and the function of the programming method described hereunder. The objective is to employ a programming method that allows shifting the HRS profile towards high R values from the conventional high resistive state HRS_{Conv} to a high resistive state HRS_{Inv} obtained thanks to the method according to the invention. Then, a margin Marg is introduced, or widened if it was already present, between the low and high resistive states of the ReRAM.

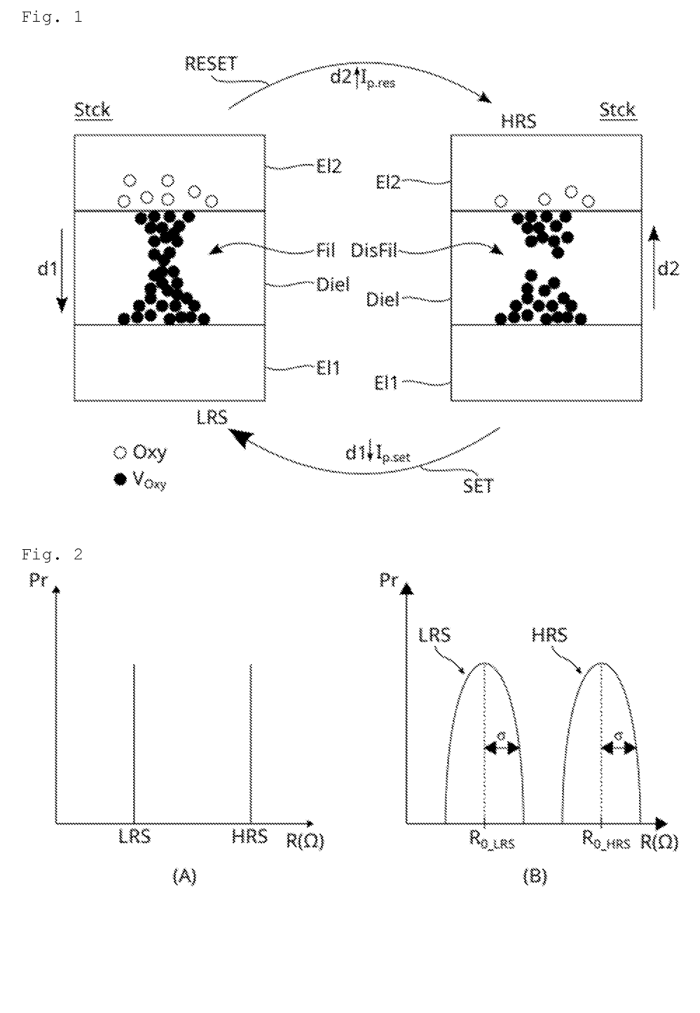

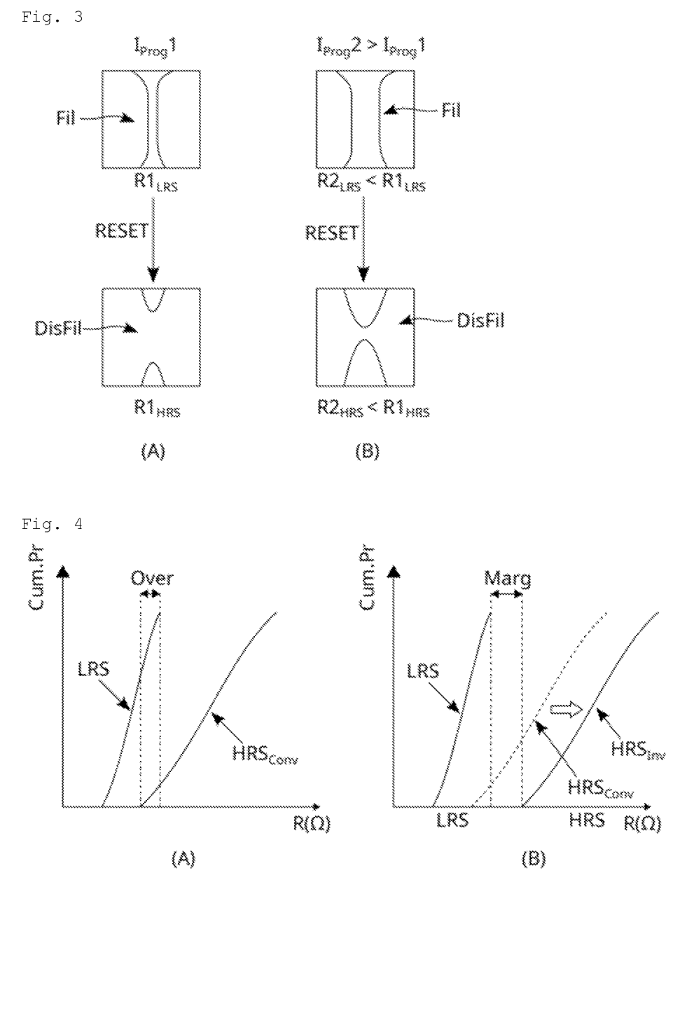

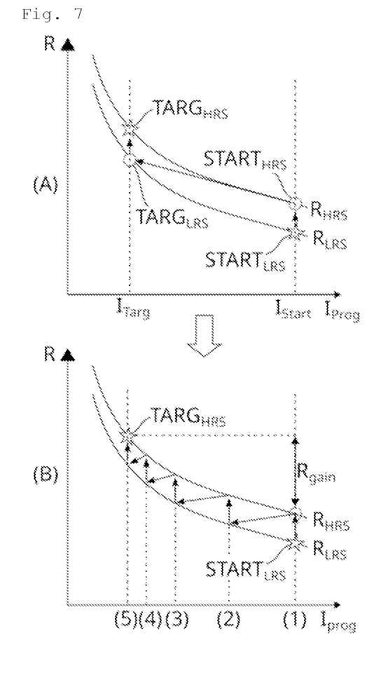

In other words, it is necessary to obtain a higher resistive value for the HRS state of a memory element in a ReRAM than is conventionally achieved. The method devised by the inventors is based on the principle of better dissolving a filament formed in the memory element than is usually achieved. This principle is implemented by the method 100 of FIG. 5, applied to a memory element Stck of a ReRAM such as the one illustrated by FIG. 1.

For the sake of setting the memory element in a state in which the method is applicable, a preliminary low resistive state programming step LRS_{prog} of the memory element is performed. This programming forms an electrically conductive filament Fil in the dielectric layer Diel that is otherwise electrically insulating.

In the present embodiment, the programming step LRS_{prog} consists in programming the memory element in LRS by a programming set operation SET_{prog} at a step S90. The operation SET_{prog} is carried out by applying a voltage to the electrodes El1 and El2 of the memory element so as to circulate a nominal programming current I_{p.set} having an absolute current value Iₙₒₘ in the first direction d1 through the stack Stck. The absolute current value and the flow direction of the current are chosen to form the filament Fil.

Next, at a step S105, an order to program the memory element Stck to HRS is received, and a high resistive state programming step HRS_{prog} of the memory element is then performed according to the following steps S110 to S140.

At a first step S110 of programming the memory element in HRS, a programming reset operation RESET_{prog} is carried out by applying a constant voltage to the electrodes El1 and El2 of the memory element so as to circulate a programming reset current I_{p.res} that will be, initially, of approximately the same absolute value Iₙₒₘ as I_{p.set} but in the second direction d2 in the stack Stck, opposite to the first direction, before decreasing and converging toward the current circulating in the HRS state of the memory element. The initial reset current may have an absolute value different from Iₙₒₘ.

At a step S120, a first read operation READ is carried out on the resistive element Stck in order to measure its resistive value R after the first step S110 of programming the memory element in HRS.

Following the first read operation of step S120, a test step S130 is performed in which the read value R is compared to a threshold value R_{Th} that is considered as the lowest acceptable resistive value for the high resistive state HRS of the memory element.

If the read value R is greater than or equal to the threshold value R_{Th}, then the method is allowed to stop at an END step S150. In this situation, it is considered that the resistive value is sufficient to ensure a proper functioning of the memory, with a margin between LRS and HRS that satisfies predetermined specifications for this memory.

If, however, the read value R is lower than the threshold value R_{Th}, then the method proceeds to a reconditioning step S140, that constitutes the core of the method to increase the resistive value R of the memory element above the threshold value R_{Th}.

The reconditioning step S140 comprises a number n of cycles comprising each a reconditioning set operation SET_{rec} followed by a reconditioning reset operation RESET_{rec}. The number n is an integer than ca be comprised between 1 and 30, preferably between 1 and 20.

The reconditioning reset operation RESET_{rec} is carried out by applying a voltage to the electrodes El1 and El2 of the memory element so as to circulate a reconditioning reset current I_{rec.res} in the second direction d2, through the memory element Stck.

The reconditioning reset current I_{rec.res} can optionally be identical to the programming reset current I_{p.res} of the programing reset operation RESET_{prog} of step S110, i.e. the characteristics of the current (direction, intensity, duration of the applied voltage) employed to dissolve the filament Fil can be the same as those of the current I_{p.res} used to write normally the HRS as at the step S110.

In contrast, the set operations SET_{rec} of the reconditioning step S140 differ from the regular LRS programming set operation SET_{prog} of the ReRAM, i.e. the current I_{rec.set} employed to form the filament Fil in the reconditioning step S140 is different from the current I_{p.set} used to write normally the LRS at the step S90. The intensity of the reconditioning set current I_{rec.set} is lower in absolute value than the current I_{p.set} used in regular set operations of the ReRAM memory: |I_{rec.set}| < |I_{p.set}|.

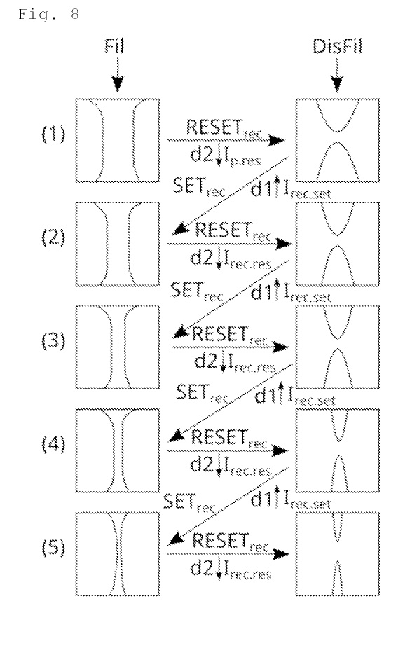

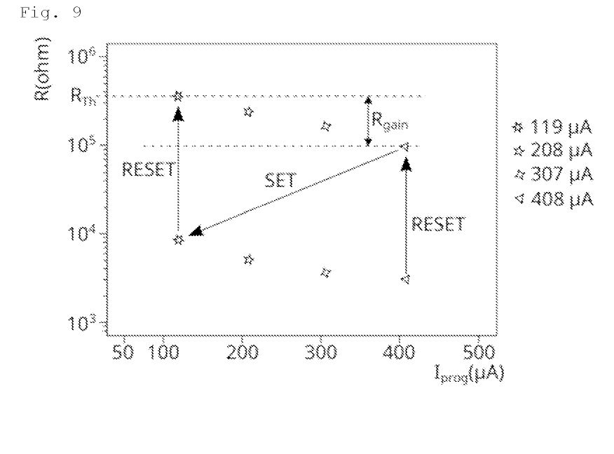

FIGS. 7 and 8 help in explaining the principle of the reconditioning step S140.

FIG. 7 shows at (A) the plotted resistive values for low and high resistive states R_{LHS} and R_{HRS} of a memory element as a function of the programming current absolute value I_{prog} used to write these states with conventional set and reset operations.

If we start from a low resistive state START_{LRS} written by a relatively high value I_{Start} of the programming current, a reset operation using the same I_{prog} value will write a high resistive state START_{HRS} that still has a resistive value much lower than a resistive value of a target low resistive state TARG_{HRS}. This is due to the phenomena illustrated by FIG. 3 and discussed previously.

In order to write the high resistive state TARG_{HRS}, one may consider starting from the high resistive state START_{HRS}, then reducing the programming current to the current I_{Targ} corresponding to that of the high resistive state TARG_{HRS} on the plot to write the corresponding low resistive state TARG_{LRS} and then applying a reset operation to attain the target state TARG_{HRS}. However, such a scheme is not feasible, as, in the scenario of FIG. 7(A), the resistive value of the starting high resistive state START_{HRS} is lower than the resistive value of the target low resistive state TARG_{LRS}.

To circumvent this impossibility, the method consists in employing, when necessary, a succession of cycles each comprising a set operation followed by a reset operation, that allows to progressively attain the target high resistive state TARG_{HRS} even when starting from the low resistive state STARTLRS, as illustrated by FIG. 7(B). For the reasons explained below in relation with FIG. 8, the current employed has to be lower than the current initially employed to write the state START_{LRS}.

In the scenario illustrated by FIG. 7(B), 9 steps are necessary to write the state TARG_{HRS} from the state START_{LRS}, and there is no situation in which passing from an HRS to an LRS would imply increasing the resistive value, which was the impossibility mentioned in the scenario of FIG. 7(A). These 9 steps are distributed among 5 pairs of LRS and HRS identified as (1) to (5).

In a conventional writing method where the resistive of the memory element goes essentially back and forth between two resistive states in an unidimensional fashion, along the Y-axis of the graphs of FIG. 7. In contrast, the programming method 100 of FIG. 4 advantageously allows moving the resistive value in both the X-axis and the Y-axis of the graphs, allowing more flexibility in the programming of a ReRAM memory. In this example, we can see the achievable resistive value has gained a resistance R_{gain}, the represents the difference between the resistive values of the states R_{HRS} and TARG_{HRS}.

FIG. 8 Explains phenomenologically the response of the dielectric layer of the memory element Stck to the successions of steps illustrated by FIG. 7(B).

On the left-hand side of FIG. 8 are represented the filaments Fil formed by the successive set operations and on the right-hand side of FIG. 8 are represented the dissolved filament DisFil obtained by the successive reset operations, for each of the 5 pairs of LRS and HRS identified as (1) to (5) In FIG. 7(B).

The principle is to start from a thick filament Fil, needed to have a low resistive value, and reducing the thickness of the filament by repetitively dissolving it and reforming it thinner than it was previously, in successive cycles carried out as the step S140. In this manner, the filament obtained at the last pair of states (5) is thin, and can be easily dissolved so as to obtain a state HRS having a high resistive value. Generally speaking, the number of pairs of states equals the repetition number n of SET_{rec}/RESET_{rec} cycles. FIG. 8 represents a first reset operation that corresponds to the programming reset operation of step S110 that employs the current I_{p.res}, and following reset operations that employs the current I_{rec.res}. The set operations are performed with the current I_{rec.set}. In this example, 4 cycles comprising each one SET_{rec} operations and one RESET_{rec} operation are performed.

The step S140 changes the resistive value R of the memory element to a value R_{rec} that is to be read during a new step S120, considered as the new R value and compared to the threshold value R_{Th} at a new test step S130.

If the threshold value R_{Th} is still greater than the read R value, then step S140, S120 and S130 are performed again, until the resistive value R becomes greater than or equal to the threshold value R_{Th}, in which case the method comes to an end at the step S150.

As illustrated by FIG. 6, the method of FIG. 5 can be implemented by any conventional ReRAM memory, programmed to carry out the steps of the method 100 detailed above. More specifically, the set, reset and read operations can consist in applying command voltages to the electrodes El1 and El2 in the form of pulses (application of voltages for finite periods of time), that result in generating circulating pulses of currents of intensity into a memory element, as conventionally well known. Fig. is a graph representing applied currents of intensity I as a function of time t. FIG. 6 is merely a schematic illustration, and intensities, lengths, profiles of the represented pulses are not intended to be restricted to this.

During a set operation, a voltage is applied, generating a circulating current in the memory element, that has to be limited so as to prevent damaging the memory, as forming the filament and thus reducing the resistance of the current leads to a rise of the current, that has to be capped to prevent damaging the memory.

During a reset operation, a voltage of same order of magnitude but opposite sign as the voltage used during the set operation may be used, generating a current initially substantially the same as the current running in the memory element at the end of the set operation. With the dissolution of the filament, this current decreases with resistance increase.

Voltages necessary to generate the currents adapted to the set, reset and read operations may differ with the ReRAM technology and the electronic set-up of a memory cell, an array of memory elements, or, more generally, the electronic circuits employed to control the ReRAM.

On the other hand, the current values are better defined. FIG. 9 shows a graph that can be used to determine an appropriate current value to implement the programming set operation SET_{prog} and the reconditioning set operation SET_{rec}. The nominal programming current is fixed by the retention requirements: the current needs to be strong enough to form a filament sufficiently thick to bring a high enough retention capacity. The current for the reconditioning operation needs to be weak enough so that the filament that it forms can be efficiently dissolved by a reset operation so that the resistive value of the high resistive state is higher than a given threshold, fixed by the specifications of the ReRAM.

Writing tests of LRS and HRS have been performed for 4 values (408 µA, 307 µA, 208 µA, 119 µA) of the programming current for the set and reconditioning operations SET_{prog} and SET_{rec}. In this example, it can be seen that the higher the current, the lower the resistive value of the LRS is, and that the lower the current, the higher the resistive value of the LRS is. Here, the current needs to be as low as 119 µA for the resistive value of the HRS state to attain a threshold value R_{Th} and be deemed acceptable. As illustrated, one can estimate a gain in the resistive value of the high resistive state by comparing the resistive value for two distinct programming currents, the 408 µA current and the 119 µA current in FIG. 9.

Practically speaking, by proceeding as illustrated above, favorable values for the current of the set operation SET_{prog} can be defined as comprised between 175 µA and 225 µA. A current of a same absolute value can be employed for the reset operations RESET_{prog} and RESET_{rec}. Conversely, favorable values for the current of the reconditioning operation SET_{rec} are lower than the values for the current of the set operation SET_{prog} and can be defined as comprised between 75 µA and 125 µA.

The number n of cycles necessary to reach a resistive value acceptable for the HRS can be empirically determined by experience.

Alternatively, as illustrated by the method 100 of FIG. 5, the reconditioning can be employed only when necessary, following read and test operations.

The read and test operation could be performed between each cycle, which would correspond to n = 1 in the diagram of FIG. 5. This specific variant has for inconvenient a loss in speed when several cycles are necessary. On the other hand, it limits the number of set and reset operations, limiting the wear of the memory element and thus enhancing retention capability and reliability.

Alternatively, a fixed number n of cycle, with n > 1 may be performed between two test operations. This specific variant may be advantageous in terms of speed when a high number of cycles is necessary to reach the threshold value R_{Th} since it allows limiting the number of reset and test operations.

The stack Stck described above can form the active elements of a ReRAM memory MEM. The set, reset and read operations can be applied to bit cells integrated in an array ARR, each of the bit cells comprising a stack Stck.

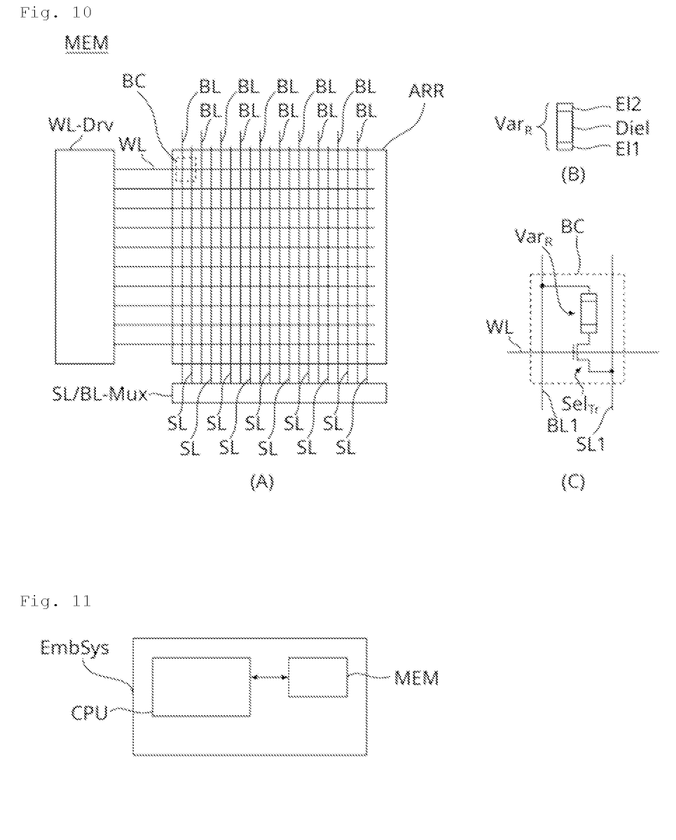

FIG. 10 illustrates a basic, conventional structure of a resistive memory MEM. Such a memory is described for example in the patent US11735260B2.

Typically, as illustrated by FIG. 10(C), each bit cell BC of the array ARR comprises (i) one stack Stck that forms a variable resistor Var_{R} (see FIG. 10(B)) and fulfills the function of a memory bit element for each bit cell, and (ii) one selection transistor Sel_{Tr} having a source and a drain connected in series with the variable resistor.

An array ARR of bit cells typically comprises columns and rows of bit cells, as illustrated by FIG. 10(A). Each column comprises (i) a bit line BL connected to a source and a drain of the transistor Sel_{Tr} through the variable resistor Var_{R} for each of the bit cells of the column and (ii) a source line SL connected to the bit line BL through the source and the drain of the transistor SelTr and the variable resistor Var_{R}. Each row of bit cells comprises a word line WL connected to the gate of the selection transistor Sel_{Tr} for each of the bit cells of the row. The bit lines BL and the source lines SL are each connected to and controlled through a column multiplexer circuit SL/BL-Mux. The word lines WL are each connected to and controlled by a row driver circuit WL-Drv.

FIG. 11 illustrates an embedded system EmbSys integrating a OxRAM in communication with a microprocessor CPU. Such a system can be a portable semiconductor device configured to treat numerical data. Generally speaking, any embedded device conventionally employing a flash memory may employ a resistive memory instead. The OxRAM can benefit from the enhanced retention capability of the stack Stck described above and can make it especially suited for high temperatures applications such as transport applications.

Other variations to the disclosed embodiments can be understood and effected by those skilled in the art in practicing the claimed invention, from a study of the drawings, the disclosure, and the appended claims.

What is claimed is:

1. A method of programming a high resistive state of a memory element part of a resistive random access memory, the random access memory being configured to program a low resistive state of the memory element by running a nominal programming current in a first direction through the memory element, the method comprising:
an initial step of writing the high resistive state of the memory element, consisting in running a reset current through the memory element in a second direction, opposite to the first direction; and
a reconditioning step following the initial step of writing the high resistive state, the reconditioning step comprising at least one cycle of operations comprising, in this order:
a reconditioning set operation that consists in running a reconditioning set current in the first direction through the memory element, the reconditioning set current having an absolute value lower than the nominal programming current; and
a reconditioning reset operation that consists in running a reconditioning reset current in the second direction through the memory element,
wherein the reconditioning step increases the resistive value of the memory element obtained by the initial step of writing the high resistive state.

2. The method according to claim 1, further comprising:
a first read operation measuring a resistive value of the memory element after the initial step of performing the reset operation; and
a test step in which the measured resistive value is compared to a threshold value,
wherein the reconditioning step is performed when the measured resistive value is lower than the threshold value.

3. The method according to claim 1, further comprising:
a second read operation measuring a reconditioned resistive value of the memory element after the reconditioning step has been performed; and
a second test step in which the measured reconditioned resistive value is compared to the threshold value,
wherein the reconditioning step is performed again when the measured reconditioned resistive value is lower than the threshold value.

4. The method according to claim 1, wherein the reconditioning step comprises exactly one occurrence of the cycle of operations.

5. The method according to claim 1, wherein the reconditioning step comprises more than one occurrence of the cycle of operations.

6. The method according to claim 5, wherein the reconditioning step comprises more than one and less than 20 occurrences of the cycle of operations.

7. The method according to claim 1, wherein:
the nominal programming current has an absolute value comprised between 175 µA and 225 µA, and
the reconditioning set current has an absolute value comprised between 75 µA and 125 µA.

8. The method according to claim 1, wherein:
the initial step of writing the high resistive state of the memory element dissolves an electrically conductive filament formed in the memory element;
the reconditioning set operation reforms the dissolved filament; and
the reconditioning reset operation dissolves the reformed filament.

9. The method according to claim 1, wherein the method is performed during a normal operation of the resistive random access memory, and not during a manufacturing stage and/or initialization of the resistive random access memory.

10. A ReRAM memory device comprising an array of bit cells controlled by a column multiplexer circuit and a row driver circuit configured to write a high resistive state of a memory element of the bit cell according to the method of claim 1.

11. The ReRAM memory device according to claim 10, the ReRAM being an OxRAM.

12. An embedded system comprising a microprocessor and the memory device according to claim 10 arranged to be in communication with the microprocessor.
